(19) United States
(12) Patent Application Publication
(10) Pub. No.: US 2021/0343912 A1
(43) Pub. Date: Nov. 4, 2021

(54) LED PACKAGING STRUCTURE WITH HIGH SIDE BRIGHTNESS

(71) Applicant: ZHANGZHOU GO WIN LIGHTING CO., LTD, ZHANGZHOU (CN)

(72) Inventors: QINGAN WU, ZHANGZHOU (CN); XIONGZHONG LIN, ZHANGZHOU (CN); YAO LIU, ZHANGZHOU (CN)

(21) Appl. No.: 16/888,884

(22) Filed: Jun. 1, 2020

(30) Foreign Application Priority Data
Apr. 30, 2020 (CN) 202020715067.4

(51) Int. Cl. H01L 33/60; H01L 33/54; H01L 33/62; H01L 33/64

(52) U.S. Cl. CPC H01L 33/60; H01L 33/647; H01L 33/62; H01L 33/54

(57) ABSTRACT

Disclosed is an LED packaging structure with high side brightness, including a positive electrode bracket; a negative electrode bracket, spaced apart from the positive electrode bracket, and the top ends of the positive electrode bracket and the negative electrode bracket are both planar structures; an LED chip, flip-chip mounted on the top ends of the positive electrode bracket and the negative electrode bracket, a cylindrical packaging colloid, packaged on the periphery of the positive electrode bracket and the negative electrode bracket and the LED chip, an end of the cylindrical packaging colloid away from the positive electrode bracket and the negative electrode bracket is provided with a reflective bowl with a concave structure. The light is emitted to the outside from the center of LED chip, the LED chip is not blocked by the bracket as much as possible.

### CROSS REFERENCE TO RELATED APPLICATIONS

This application claims all benefits accruing under 35 U.S.C. § 119 from China Patent Application No. 202020715067.4 filed on Apr. 30, 2020, in the State Intellectual Property Office of China, the disclosure of which is incorporated herein by reference in its entirety.

### TECHNICAL FIELD

The disclosure generally relates to the field of LED packaging structure, and more particularly to an LED packaging structure with high side brightness.

### BACKGROUND

When electrons and holes recombine, they can radiate visible light, so they can be used to make LED chips, used as indicator light in circuit and instrument, or composed of text or number display. Gallium arsenide diodes emit red light, gallium phosphide diodes emit green light, silicon carbide diodes emit yellow light, and gallium nitride diodes emit blue light. Due to the chemical nature, it is divided into organic LED chip and OLED and inorganic LED chip.

LED lights for decoration, such as LED lights for Christmas tree decoration, need to get higher brightness on the side, to give people a more beautiful and brighter feeling. The traditional LED packaging structure requires a concave bowl opening on the bracket for placing the LED chip, this structure blocks the angle of light emitted by the LED chip. When the human eye looks from the side, the LED chip gives a different impression.

The purpose of this disclosure is to design an LED packaging structure with high side brightness for the above existing technical problems.

### SUMMARY OF DISCLOSURE

In view of the problems existing in the prior art, the disclosure provides an LED packaging structure with high side brightness, and can effectively solve the problems existing in the prior art.

The technical scheme of the disclosure is:

An LED packaging structure with high side brightness, comprising:

a positive electrode bracket:

a negative electrode bracket, which is spaced apart from the positive electrode bracket, and the top ends of the positive electrode bracket and the negative electrode bracket are both planar structures;

an LED chip, which is flip-chip mounted on the top ends of the positive electrode bracket and the negative electrode bracket, and a positive electrode of the LED chip is electrically connected to the positive electrode bracket and a negative electrode of the LED chip is electrically connected to the negative electrode bracket;

a cylindrical packaging colloid, packaged on the periphery of the positive electrode bracket and the negative electrode bracket and the LED chip, an end of the cylindrical packaging colloid away from the positive electrode bracket and the negative electrode bracket is provided with a reflective bowl with a concave structure, the reflective bowl is directly opposite to the LED chip, and the reflective bowl is used to reflect part of the light of the LED chip to the side.

Further, the positive electrode of the LED chip is welded to the positive electrode bracket, the negative electrode of the LED chip is welded to the negative electrode bracket.

Further, the part of the positive electrode bracket and the negative electrode bracket near the LED chip is provided with a heat dissipation portion extending outside.

Further, the reflective bowl is a conical concave structure.

Further, the distance D between the reflective bowl and the LED chip is 1-8 mm.

Further, the cone angle θ of the reflective bowl is between 95-115°.

Further, 0=−7.7281n(D)+110.67 and is a relationship between the cone angle θ and the distance D.

A decorative lighting, comprising the LED packaging structure above mentioned.

The technical scheme has the following technical effects:

1. The light is emitted to the outside from as the center of LED chip, only a small angle of light is blocked by the positive electrode bracket or the negative electrode bracket, the light of the other angle is emitted to the outside. The light at the angle toward the reflective bowl is reflected by the reflective bowl, and the direction of its optical path becomes the side of the reflecting bowl under the action of the reflecting bowl. Therefore, the LED chip is not blocked by the bracket as much as possible, and under the synergy of the reflection effect of the reflective bowl, the human eye can feel the higher brightness of the LED chip on the side of the LED chip.

2. Due to the cooperation of the LED chip and the reflective bowl and its peripheral structure, the human eye can see the two independent optical paths of the LED chip and the reflective bowl, human eye has the feeling of two light sources. So, the brightness feeling of the present invention is improved.

3. LED is directly is flip-chip and welded to the bracket, LED is not gold wire welded. Therefore, the LED packaging structure avoids the LED failure caused by the bad welding and breaking of the gold wire, and improving the yield rate. And it is easier to weld and improve production efficiency.

### BRIEF DESCRIPTION OF DRAWINGS

FIG. 1 is a structural diagram of the disclosure.

FIG. 2 is a schematic diagram of light direction.

FIG. 3 is a schematic diagram of human perception of this invention.

FIG. 4 is the trend curve of the angle θ and the distance D.

### DETAILED DESCRIPTION

To facilitate the understanding of those skilled in the art, the structure of the disclosure is further described in detail in connection with the accompanying drawings:

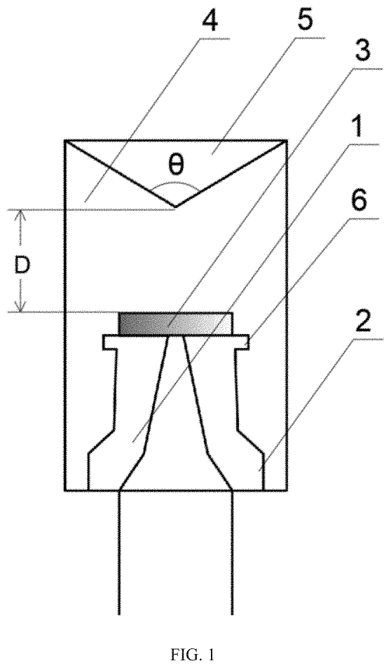

One embodiment of the disclosure, referring to FIG. 1, is an LED packaging structure with high side brightness, comprising:

a positive electrode bracket 1;

a negative electrode bracket 2, which is spaced apart from the positive electrode bracket 1, and the top ends of the positive electrode bracket 1 and the negative electrode bracket 2 are both planar structures;

an LED chip 3, flip-chip mounted on the top ends of the positive electrode bracket 1 and the negative electrode bracket 2, and a positive electrode of the LED chip 3 is electrically connected to the positive electrode bracket 1 and a negative electrode of the LED chip 3 is electrically connected to the negative electrode bracket 2;

a cylindrical packaging colloid 4, packaged on the periphery of the positive electrode bracket 1 and the negative electrode bracket 2 and the LED chip 3, an end of the cylindrical packaging colloid 4 away from the positive electrode bracket 1 and the negative electrode bracket 2 is provided with a reflective bowl 5 with a concave structure, the reflective bowl 5 is directly opposite to the LED chip 3, and the reflective bowl 5 is used to reflect part of the light of the LED chip 3 to the side.

Specifically, the positive electrode of the LED chip 3 is welded to the positive electrode bracket 1, the negative electrode of the LED chip 3 is welded to the negative electrode bracket 2.

Specifically, the part of the positive electrode bracket 1 and the negative electrode bracket 2 near the LED chip 3 is provided with a heat dissipation portion 6 extending outside.

Specifically, the reflective bowl 5 is a conical concave structure.

Specifically, the distance D between the reflective bowl 5 and the LED chip 3 is 1-8 mm.

Specifically, the cone angle θ of the reflective bowl 5 is between 95-115°.

Specifically, θ=−7.7281n(D)+110.67 and is a relationship between the cone angle θ and the distance D.

Working principle: the positive electrode bracket 1 and the negative electrode bracket 2 are mounted at the same high, and the LED chip 3 is flip-chip mounted between the positive electrode bracket 1 and the negative electrode bracket 2. Therefore, the height of the LED chip 3 is higher than the positive electrode bracket 1 or the negative electrode bracket 2, and the positive electrode bracket 1 or the negative electrode bracket 2 is not provided with a groove for positioning the LED chip 3, and also is not provide a peripheral convex edge for auxiliary positioning of the LED chip 3. The LED chip 3 is flip-chip and directly welded between the positive electrode bracket 1 or the negative electrode bracket 2, therefor, the light from the LED chip 3 can be scattered to the outside as large an angle as possible.

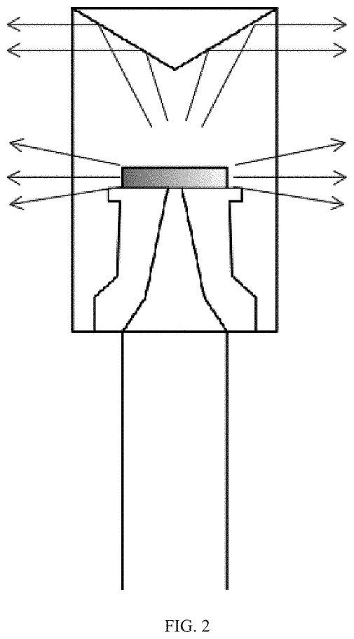

Referring to FIG. 2, the light as the center of LED chip 3 is emitted to the outside, only a small angle of light is blocked by the positive electrode bracket 1 or the negative electrode bracket 2, the other angle of the light is emitted to the outside. The light at the angle toward the reflective bowl 4 is reflected by the reflective bowl 4, and the direction of its optical path becomes the side of the reflecting bowl 4 under the action of the reflecting bowl 4. Therefore, the LED chip 3 is not blocked by the bracket as much as possible, and under the synergy of the reflection effect of the reflective bowl 4, the human eye can feel the higher brightness of the LED chip 3 on the side of the LED chip 3.

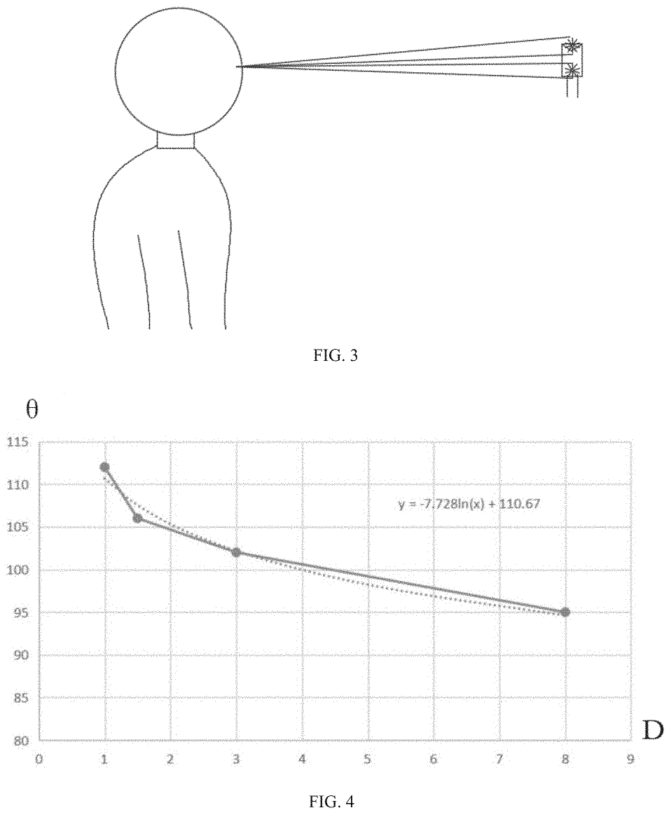

Referring to FIG. 3, due to the cooperation of the LED chip 3 and the reflective bowl 4 and its peripheral structure, the human eye can see the two independent optical paths of the LED chip 3 and the reflective bowl 4, human eye has the feeling of two light sources. So, the brightness feeling of the present invention is improved.

Referring to FIG. 3, which is the trend curve of the angle θ and the distance D.

### Embodiment 1

In this embodiment, the distance between the reflective bowl 4 and the LED chip 3 is D, D=8 mm. The cone angle of the reflecting bowl 4 is θ, θ=95°. The side lumen of this embodiment is 5.12 lm. The side lumen of the existing LED packaging structure is 3.78 lm. The side lumen is increased by 35.4%.

### Embodiment 2

In this embodiment, the distance between the reflective bowl 4 and the LED chip 3 is D, D=3 mm. The cone angle of the reflecting bowl 4 is θ, θ=102°. The side lumen of this embodiment is 5.23 lm. The side lumen of the existing LED packaging structure is 3.82 lm. The side lumen is increased by 36.9%.

### Embodiment 3

In this embodiment, the distance between the reflective bowl 4 and the LED chip 3 is D, D=1.5 mm. The cone angle of the reflecting bowl 4 is θ, θ=106°. The side lumen of this embodiment is 5.96 lm. The side lumen of the existing LED packaging structure is 4.23 lm. The side lumen is increased by 40.8%.

### Embodiment 4

In this embodiment, the distance between the reflective bowl 4 and the LED chip 3 is D, D=1 mm. The cone angle of the reflecting bowl 4 is θ, θ=112°. The side lumen of this embodiment is 6.12 lm. The side lumen of the existing LED packaging structure is 4.22 lm. The side lumen is increased by 45.0%.

### Embodiment 5

A decorative lighting, comprising the LED packaging structure above mentioned.

The foregoing description is only a preferred embodiment of the disclosure, and all changes and modifications to the patent scope applied for in accordance with the disclosure shall belong to the scope covered by the disclosure.

1. An LED packaging structure with high side brightness, comprising:
a positive electrode bracket;
a negative electrode bracket, spaced apart from the positive electrode bracket, and top ends of the positive electrode bracket and the negative electrode bracket are both planar structures;
an LED chip, flip-chip mounted on the top ends of the positive electrode bracket and the negative electrode bracket, and a positive electrode of the LED chip is electrically connected to the positive electrode bracket and a negative electrode of the LED chip is electrically connected to the negative electrode bracket;
a cylindrical packaging colloid packaged on the periphery of the positive electrode bracket and the negative electrode bracket and the LED chip, an end of the cylindrical packaging colloid away from the positive electrode bracket and the negative electrode bracket is provided with a reflective bowl with a concave structure, the reflective bowl is directly opposite to the LED chip, and the reflective bowl is used to reflect part of light of the LED chip to the side, a distance D between the reflective bowl and the LED chip is 1-8 mm, the reflective bowl is a conical concave structure, and a relationship between the cone angle θ and the distance D is θ=−7.7281n(D)+110.67.

2. The LED packaging structure with high side brightness according to claim 1, wherein the positive electrode of the LED chip is connected to the positive electrode bracket by welding, the negative electrode of the LED chip is connected to the negative electrode bracket by welding.

3. The LED packaging structure with high side brightness according to claim 1, wherein a part of the positive electrode bracket and the negative electrode bracket near the LED chip is provided with a heat dissipation portion extending outside.

4-7. (canceled)

8. A decorative lighting, comprising an LED packaging structure, wherein the LED packaging structure with high side brightness comprises:
a positive electrode bracket;
a negative electrode bracket, spaced apart from the positive electrode bracket, and top ends of the positive electrode bracket and the negative electrode bracket are both planar structures;
an LED chip, flip-chip mounted on the top ends of the positive electrode bracket and the negative electrode bracket, and a positive electrode of the LED chip is electrically connected to the positive electrode bracket and a negative electrode of the LED chip is electrically connected to the negative electrode bracket;
a cylindrical packaging colloid packaged on the periphery of the positive electrode bracket and the negative electrode bracket and the LED chip, an end of the cylindrical packaging colloid away from the positive electrode bracket and the negative electrode bracket is provided with a reflective bowl with a concave structure, the reflective bowl is directly opposite to the LED chip, and the reflective bowl is used to reflect part of light of the LED chip to the side, a distance D between the reflective bowl and the LED chip is 1-8 mm, the reflective bowl is a conical concave structure, and a relationship between the cone angle θ and the distance D is θ=−7.7281n(D)+110.67.
